(19) United States
(12) Patent Application Publication
(10) Pub. No.: US 2026/0098337 A1
(43) Pub. Date: Apr. 9, 2026

(54) METAL CHLORIDE PRECURSORS AND DEPOSITION OF METAL-CONTAINING FILMS

(71) Applicant: L'Air Liquide, Société Anonyme pour I'Etude et I'Exploitation des Procédés Georges Claude, Paris (FR)

(72) Inventors: Su-Hyun KIM, Seoul (KR); Junhyun SONG, Seoul (KR); Jooho LEE, Seoul (KR); Daehyeon KIM, Hwaseong (KR); Wontate NOH, Seoul (KR)

(21) Appl. No.: 18/908,053

(22) Filed: Oct. 7, 2024

(51) Int. Cl. C23C 16/40; C07F 7/00; C23C 16/44; C23C 16/455; H01M 4/36

(52) U.S. Cl. CPC C23C 16/405; C07F 7/00; C23C 16/4408; C23C 16/4417; C23C 16/45536; C23C 16/45553; C23C 16/45555; H01M 4/366

(57) ABSTRACT

A method for forming a metal-containing film comprises:
a) exposing a substrate to a vapor of a metal-containing film-forming composition:
b) exposing the substrate to a co-reactant; and
c) repeating the steps of a) and b) until a desired thickness of the metal-containing film is deposited on the substrate using a vapor deposition process, wherein the metal-containing film-forming composition comprises a metal chloride precursor having the formula:

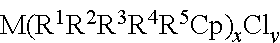

wherein, M is a transition metal, a rare earth element, an alkali metal, or an alkaline earth metal; R¹, R², R³, R⁴ and R⁵ each are independently selected from a hydrogen atom, a C₁ to C₁₀ linear or branched alkyl-group, a C₃ to C₁₀ cyclic alkyl- group, or F, Si, Ge containing C₁ to C₁₀ linear and branched alkyl chain; x and y are integers; provided that x+y equals to the oxidation state of M.

### TECHNICAL FIELD

The present invention relates to metal-containing film-forming compositions comprising metal chloride precursors, methods of synthesizing the metal chloride precursors, and methods of forming metal containing films via chemical vapor deposition (CVD) processes using the metal-containing film-forming compositions. In particular, relates to the metal chloride precursors that have low melting point with a good ALD process performance.

### BACKGROUND

Ferroelectrics have been extensively investigated for various applications, such as non-volatile ferroelectric memories, infrared detectors, microwave electronics, piezoelectric sensors, and nonlinear optical devices. Ferroelectric memories, in particular, have garnered significant attention as potential candidates for emerging memory concepts that prioritize fast read/write speed, low power consumption, and high reliability. Since the first 4-kbit capacitor-type ferroelectric random access memory (FeRAM) based on Pb(ZrₓTi₁₋ₓ)O₃ (PZT) was developed in 1993, FeRAMs have been widely adopted in the fields of IC-card, smart electric meters, and medical instruments. However, a series of drawbacks of conventional ferroelectric thin films, such as SrBi₂Ta₂O₉(SBT) and PZT, limits the development of their memory devices. An obvious degradation of ferroelectricity occurs when the film is scaled down below ˜70 nm. In addition, ion diffusions such as those of lead and bismuth are incompatible to the complementary metal-oxide-semiconductor (CMOS) process platform. Ferroelectric thin films are also susceptible to damage caused by the inevitable hydrogen that is generated from the back-end of line (BEOL) process. Therefore, the manufacturing process of commercialized FeRAMs stagnated at the 130 nm CMOS technology node, limiting their extensive applications despite their excellent performance. Another type of ferroelectric memory device is the ferroelectric field-effect transistor (FeFET), which integrates a ferroelectric thin film into a gate stack of metal-oxide-semiconductor field-effect transistors (MOSFET). Non-volatile memory can be realized by modulating the carrier inversion and accumulation near the semiconductor surface through the polarization state of the ferroelectric thin film. However, the intrinsic properties of perovskite ferroelectrics, such as a small coercive field and high permittivity, lead to poor retention of FeFETs.

Hafnium oxide (HfO₂) is a ferroelectric in nature and a colorless solid. The band gap of HfO₂ is between 5.3 and 5.7 eV. Hafnium oxides has been used as a gate dielectric in CMOS application in place of silicon oxide. Recently, HfO₂ film is considered for gap filling progress by using HfCl₄. However, HfCl₄ has some drawback such as high chlorine impurity level, particle and storage issues due to its high melting point, and low vapor pressure.

Attempts of forming HfO₂ using chlorinated hafnium or other metal precursors have been disclosed. A Hf precursor that has a low chlorine impurity level and a low melting point is required.

US 2007/0259111 A1 to Singh et al. discloses forming hafnium oxide films using chlorinated hafnium precursors such as Hf(^{t}BuCp)₂Cl₂, HfCp₂Cl₂, Hf(EtCp)₂Cl₂, Hf(MeCp)₂Cl₂, Hf(Me₅Cp)Cl₃, Hf(ⁱPrCp)₂Cl₂ and Hf(ⁱPrCp)Cl₃.

JP2005209766A discloses the use of HfCpCl₃ for deposition of Hf-containing films by MOCVD.

KR100804413B1 discloses the synthesis method or ZrCpCl₃ as a precursor for deposition methods.

### SUMMARY

Disclosed is a method for forming a metal-containing film, the method comprising the steps of:
a) exposing a substrate to a vapor of a metal-containing film-forming composition;
b) exposing the substrate to a co-reactant; and
c) repeating the steps of a) and b) until a desired thickness of the metal-containing film is deposited on the substrate using a vapor deposition process,
wherein the metal-containing film-forming composition comprises a metal chloride precursor having the formula:

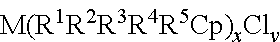

wherein, M is a transition metal, a rare earth element, an alkali metal, or an alkaline earth metal; R¹, R², R³, R⁴ and R⁵ each are independently selected from a hydrogen atom, a C₁ to C₁₀ linear or branched alkyl-group, a C₃ to C₁₀ cyclic alkyl- group, or F, Si, Ge containing C₁ to C₁₀ linear and branched alkyl chain; x and y are integers; provided that x+y equals to the oxidation state of M. The disclosed method may include one or more of the following features:
further comprising the step of introducing an inert gas purge following the steps a) and b), respectively, to separate each exposure, wherein the inert gas purge uses an inert gas selected from N₂, He, Ar, Kr, or Xe;
R¹ to R⁵ each being independently selected from H, Me, Et, nPr, Pr, sPr, tBu, sBu, iBu, nBu, tAmyl, sec-pentyl, SiMe₃, SiMe₂H, or SiH₂Me;
further comprising the step of plasma treating the co-reactant;
the co-reactant being selected from the group consisting of O₂, O₃, H₂O, H₂O₂, NO, N₂O, NO₂, oxygen containing radicals such as O—OH—, carboxylic acids, formic acid, acetic acid, propionic acid, and mixtures thereof;
the co-reactant being selected from the group consisting of H₂, H₂CO, N₂H₄, NH₃, a primary amine, a secondary amine, a tertiary amine, trisilylamine, a hydrazine N(SiH₃)₃, B₂H₆, Si₂H₆, radicals thereof, and mixtures thereof;
the co-reactant being NH₃;
the co-reactant being O₃;
the precursor including Hf(RCp)Cl₃ and Zr(RCp)Cl₃, wherein R is selected from a hydrogen atom, a C₁ to C₁₀ linear or branched alkyl-group, a C₃-C₁₀ cyclic alkyl-group, or a F, Si, Ge C₁ to C₁₀ containing linear and branched alkyl-group;
the precursor being Hf(^{t}BuCp)Cl₃;
the precursor being Hf(^{s}PentylCp)Cl₃;
the precursor being Zr(^{s}PentylCp)Cl₃;
the vapor deposition process including chemical vapor deposition (CVD), such as, a plasma enhanced CVD (PECVD), ALD, thermal ALD, plasma enhanced ALD (PEALD), spatial ALD, and combinations thereof;
the vapor deposition process being an ALD process or a PEALD;
a deposition temperature ranging from approximately 50° C. and approximately 600° C.;
a deposition temperature ranging from approximately 100° C. to approximately 600° C.;
a deposition temperature ranging from approximately 50° C. to approximately 500° C.;
a deposition temperature ranging from approximately 100° C. to approximately 500° C.; and
a deposition temperature ranging from approximately 150° C. to approximately 500° C.

Disclosed is a method of forming an HfCLO film or coating by an ALD process on a substrate, the method comprising the steps of:
a) exposing the substrate to a vapor of Hf(^{s}PentylCp)Cl₃;
b) exposing the substrate to an oxidizer; and
c) repeating the steps of a) and b) until a desired thickness of the HfO₂ film is deposited on the substrate using the ALD process. The disclosed method may include one or more of the following features:
further comprising introducing an inert gas purge following the steps a) and b), respectively, to separate each exposure; and
the substrate being a powder, wherein the powder comprises one or more of LNMC (Lithium Nickel Manganese Cobalt Oxide), LCO (Lithium Cobalt Oxide), LFP (Lithium Iron Phosphate), and other battery cathode materials.

Disclosed is a metal-containing film-forming composition for a vapor deposition process comprising a precursor having the formula:

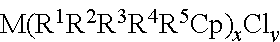

wherein, M is a transition metal, a rare earth element selected from Y or Sc, an alkali metal, or an alkaline earth metal; R¹, R², R³, R⁴ and R⁵ each are independently selected from a hydrogen atom, a C₁ to C₁₀ linear or branched alkyl-group, a C₃ to C₁₀ cyclic alkyl- group, or F, Si, Ge containing C₁ to C₁₀ linear and branched alkyl chain; x and y are integers;
provided that x+y equals to the oxidation state of M. The disclosed metal-containing film-forming composition may include one or more of the following features:
R¹ to R⁵ each being independently selected from H, Me, Et, nPr, iPr, sPr, tBu, sBu, iBu, nBu, tAmyl, sec-pentyl, SiMe₃, SiMe₂H, or SiH₂Me;
the precursor including Hf(RCp)Cl₃ and Zr(RCp)Cl₃, wherein R is selected from a hydrogen atom, a C₁ to C₁₀ linear or branched alkyl-group, a C₃-C₁₀ cyclic alkyl-group, or a F, Si, Ge containing C₁-C₁₀ linear and branched alkyl-group;
the precursor being selected from the group consisting of Hf(^{t}BuCp)Cl₃, Hf(^{s}PentylCp)Cl₃ and Zr(^{s}PentylCp)Cl₃;
the precursor being Hf(^{s}PentylCp)Cl₃; and
comprising between approximately 95% w/w and approximately 100.0% w/w of the precursor.

### Notation and Nomenclature

The following detailed description and claims utilize a number of abbreviations, symbols, and terms, which are generally well known in the art.

As used herein, the indefinite article “a” or “an” means one or more.

As used herein, “about” or “around” or “approximately” in the text or in a claim means ±10% of the value stated.

As used herein, “room temperature” in the text or in a claim means from approximately 20° C. to approximately 30° C.

The term “ambient temperature” refers to an environment temperature approximately 20° C. to approximately 30° C.

The term “substrate” refers to a material or materials on which a process is conducted. The substrate may refer to a wafer having a material or materials on which a process is conducted. The substrates may be any suitable wafer used in semiconductor, photovoltaic, flat panel, or LCD-TFT device manufacturing. The substrate may also have one or more layers of differing materials already deposited upon it from a previous manufacturing step. For example, the wafers may include silicon layers (e.g., crystalline, amorphous, porous, etc.), silicon containing layers (e.g., SiO₂, SiN, SiON, SiCOH, etc.), metal containing layers (e.g., copper, cobalt, ruthenium, tungsten, platinum, palladium, nickel, ruthenium, gold, etc.) or combinations thereof. Furthermore, the substrate may be planar or patterned. The substrate may be an organic patterned photoresist film. The substrate may include layers of oxides which are used as dielectric materials in MEMS, 3D NAND, MIM, DRAM, or FeRam device applications (for example, ZrO₂ based materials, HfO₂ based materials, TiO₂ based materials, Al₂O₃ based materials, rare earth oxide based materials, ternary oxide based materials, etc.) or nitride-based films (for example, TaN, TiN, NbN) that are used as electrodes. One of ordinary skill in the art will recognize that the terms “film” or “layer” used herein refer to a thickness of some material laid on or spread over a surface and that the surface may be a trench or a line. Throughout the specification and claims, the wafer and any associated layers thereon are referred to as substrates.

The term “wafer” or “patterned wafer” refers to a wafer having a stack of films on a substrate and at least the top-most film having topographic features that have been created in steps prior to the deposition of the Group V (five)-containing film.

The term “aspect ratio” refers to a ratio of the height of a trench (or aperture) to the width of the trench (or the diameter of the aperture).

The term “high aspect ratio” refers to an aspect ratio larger than approximately 2:1, preferably an aspect ratio ranging from approximately 2:1 to approximately 200:1.

Note that herein, the terms “film” and “layer” may be used interchangeably. It is understood that a film may correspond to, or related to a layer, and that the layer may refer to the film. Furthermore, one of ordinary skill in the art will recognize that the terms “film” or “layer” used herein refer to a thickness of some material laid on or spread over a surface and that the surface may range from as large as the entire wafer to as small as a trench or a line.

Note that herein, the terms “aperture”, “via”, “hole” and “trench” may be used interchangeably to refer to an opening formed in a semiconductor structure.

As used herein, the abbreviation “NAND” refers to a “Negative AND” or “Not AND” (electronic logic gate); the abbreviation “2D” refers to 2 dimensional gate structures on a planar substrate; the abbreviation “3D” refers to 3 dimensional or vertical gate structures, wherein the gate structures are stacked in the vertical direction.

Note that herein, the terms “deposition temperature” and “substrate temperature” may be used interchangeably. It is understood that a substrate temperature may correspond to, or be related to a deposition temperature, and that the deposition temperature may refer to the substrate temperature.

The term “film-forming composition” refers to a composition used for deposition of a film. The film-forming composition may include, but is not limited to, a precursor, a solvent and/or a carrier gas. Furthermore, the film-forming composition may include, but is not limited to, a precursor, optionally a solvent, optionally a carrier gas, and optionally one or more co-reactant(s). Herein, the precursor may be supplied either in a neat form or in a blend with a suitable solvent. The precursor may be present in varying concentrations in the solvent. Alternatively, the precursor may be vaporized by passing a carrier gas into a container that contains the precursor or by bubbling the carrier gas into the precursor. The carrier gas and precursor are then introduced into a reactor as a vapor. The co-reactant may be an oxidizer, a reducing agent, a dilute gas, an additive, an inhibitor, an additional or a secondary precursor, etc., for assisting in formation of the film. Here an inert gas selected from N₂, He, Ar, Kr, Xe may be used as the carrier gas and/or the dilute gas.

Note that herein, the terms “precursor” and “deposition compound” and “deposition gas” may be used interchangeably when the precursor is in a gaseous state at room temperature and ambient pressure. It is understood that a precursor may correspond to, or be related to a deposition compound or deposition gas, and that the deposition compound or deposition gas may refer to the precursor.

The standard abbreviations of the elements from the periodic table of elements are used herein. It should be understood that elements may be referred to by these abbreviation (e.g., Si refers to silicon, N refers to nitrogen, O refers to oxygen, C refers to carbon, H refers to hydrogen, F refers to fluorine, etc.).

As used herein, the term “hydrocarbon” refers to a saturated or unsaturated function group containing exclusively carbon and hydrogen atoms. As used herein, the term “alkyl group” refers to saturated functional groups containing exclusively carbon and hydrogen atoms. An alkyl group is one type of hydrocarbon. Further, the term “alkyl group” refers to linear, branched, or cyclic alkyl groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the term “alkyl group” refers to saturated functional groups containing exclusively carbon and hydrogen atoms. Further, the term “alkyl group” refers to linear, branched, or cyclic alkyl groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the abbreviation “Me” refers to a methyl group; the abbreviation “Et” refers to an ethyl group; the abbreviation “Pr” refers to a propyl group; the abbreviation “nPr” refers to a “normal” or linear propyl group; the abbreviation “iPr” refers to an isopropyl group; the abbreviation “Bu” refers to a butyl group; the abbreviation “nBu” refers to a “normal” or linear butyl group; the abbreviation “tBu” refers to a tert-butyl group, also known as 1,1-dimethylethyl; the abbreviation “sBu” refers to a sec-butyl group, also known as 1-methylpropyl; the abbreviation “iBu” refers to an iso-butyl group, also known as 2-methylpropyl; the abbreviation “amyl” refers to an amyl or pentyl group; the abbreviation “tAmyl” refers to a tert-amyl group, also known as 1,1-dimethylpropyl.

Please note that the metal-containing (e.g., Hf, Zr) films or layers deposited, such as hafnium chloride oxide or zirconium chloride nitride, may be listed throughout the specification and claims without reference to their proper stoichiometry (e.g., HfClO═HfClO₃). These layers may also contain Hydrogen, typically from 0 atomic % to 15 atomic %. However, since not routinely measured, any film compositions given ignore their H content, unless explicitly stated otherwise. Furthermore, the concentration of hydrogen may be further tuned by performing post deposition annealing to obtained desired thin film properties.

Ranges may be expressed herein as from about one particular value, and/or to about another particular value. When such a range is expressed, it is to be understood that another embodiment is from the one particular value and/or to the other particular value, along with all combinations within said range. Any and all ranges recited herein are inclusive of their endpoints (i.e., x=1 to 4 or x ranges from 1 to 4 includes x=1, x=4, and x=any number in between), irrespective of whether the term “inclusively” is used.

Reference herein to “one embodiment” or “an embodiment” means that a particular feature, structure, or characteristic described in connection with the embodiment may be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

As used herein, the term “independently” when used in the context of describing R groups should be understood to denote that the subject R group is not only independently selected relative to other R groups bearing the same or different subscripts or superscripts, but is also independently selected relative to any additional species of that same R group. For example in the formula MR¹ₓ (NR²R³)₍₄₋ₓ₎, where x is 2 or 3, the two or three R¹ groups may, but need not be identical to each other or to R² or to R³. Further, it should be understood that unless specifically stated otherwise, values of R groups are independent of each other when used in different formulas.

As used in this application, the word “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts in a concrete fashion.

Additionally, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

“Comprising” in a claim is an open transitional term which means the subsequently identified claim elements are a nonexclusive listing (i.e., anything else may be additionally included and remain within the scope of “comprising”). “Comprising” is defined herein as necessarily encompassing the more limited transitional terms “consisting essentially of” and “consisting of”; “comprising” may therefore be replaced by “consisting essentially of” or “consisting of” and remain within the expressly defined scope of “comprising”.

“Providing” in a claim is defined to mean furnishing, supplying, making available, or preparing something. The step may be performed by any actors in the absence of express language in the claim to the contrary.

### BRIEF DESCRIPTION OF THE DRAWINGS

For a further understanding of the nature and objects of the present invention, reference should be made to the following detailed description, taken in conjunction with the accompanying drawings, in which like elements are given the same or analogous reference numbers and wherein:

FIG. 1 is a Thermo Gravimetric Analysis (TGA) graph demonstrating the percentage of weight with increasing temperature of Hf(^{t}BuCp)Cl₃;

FIG. 2 is a TGA graph demonstrating the percentage of weight with increasing temperature of Hf(^{s}PentylCp)Cl₃;

FIG. 3 is a TGA graph demonstrating the percentage of weight with increasing temperature of Zr(^{s}PentylCp)Cl₃;

FIG. 4 is an ALD window graph for Hf(^{s}PentylCp)Cl₃ with ozone; and

FIG. 5 shows XPS analysis showing film impurities for Hf (^{s}PentylCp)Cl₃ with ozone.

### DESCRIPTION OF PREFERRED EMBODIMENTS

Disclosed are metal-containing film-forming compositions comprising metal chloride precursors, methods of synthesizing the metal chloride precursors, and methods of forming metal-containing films via chemical vapor deposition (CVD) processes, such as atomic layer deposition (ALD) process, using the metal-containing film-forming compositions. More specifically, the disclosed are the metal chloride precursors that have low melting point with a good ALD process performance.

The disclosed metal chloride precursors having the formula:

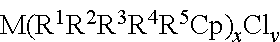

wherein, M is a transition metal, a rare earth element, an alkali metal, or an alkaline earth metal; R¹, R², R³, R⁴ and R⁵ each are independently selected from a hydrogen atom, a C₁ to C₁₀ linear or branched alkyl-group, a C₃-C₁₀ cyclic alkyl- group, or F, Si, Ge containing C₁-C₁₀ linear and branched alkyl chain; x and y are integers; provided that x+y equals to the oxidation state of M.

Exemplary disclosed metal chloride precursors include Zr(RCp)Cl₃ and Hf(RCp)Cl₃, wherein R is selected from a hydrogen atom, a C₁ to C₁₀ linear or branched alkyl-group, a C₃-C₁₀ cyclic alkyl- group, or a F, Si, Ge containing C₁-C₁₀ linear and branched alkyl-group. For example, Zr(nPrCp)Cl₃, Zr(sBuCp)Cl₃, Zr(tBuCp)Cl₃, Zr(sPentylCp)Cl₃, Hf(sPentylCp)Cl₃, Hf(sBuCp)Cl₃, Hf(tBuCp)Cl₃, or the like.

Syntheses of some Hf(RCp)Cl₃ and Zr(RCp)Cl₃ precursors (wherein R is selected from a hydrogen atom, a C₁ to C₁₀ linear or branched alkyl-group, a C₃-C₁₀ cyclic alkyl- group, or F, Si, Ge containing C₁-C₁₀ linear and branched alkyl chain, or the like), and the deposition of metal containing film with the metal chloride precursors (e.g., Hf(RCp)Cl₃ and Zr(RCp)Cl₃ precursors) are described here, and the Examples that follow.

Here Zr(nPrCp)Cl₃, Zr(sBuCp)Cl₃, Zr(tBuCp)Cl₃, Zr(sPentylCp)Cl₃ were synthesized, and their physical properties are shown in Table 1.

TABLE 1

| Precursor | ZrCpCl₄ | Zr(nPrCp)Cl₃ | Zr(tBuCp)Cl₃ | Zr(sBuCp)Cl₃ | Zr(sPentylCp)Cl₃ |
|---|---|---|---|---|---|
| Appearance | Off-white powder | Yellow solid | Yellow solid | Yellow solid | Orange solid |
| Vapor pressure | 1 torr @ 176° C. | 1 torr @ 179° C. | 1 torr @ 149° C. | 1 torr @ 164° C. | 1 torr @ 171° C. |
| Melting point | 197 | 120 | 137 | Not detected | Not detected |
| onset (° C.) | | | | | |

Regarding Hf precursors, Hf(sBuCp)Cl₃, Hf(tBuCp)Cl₃, Hf(sPentylCp)Cl₃ were synthesized. Unexpectedly, it is found that Hf(sPentylCp)Cl₃ has dramatically low melting point than other Hf(RCp)Cl₃ series as shown in Table 2. This creation has tremendous advantages in terms of deposited film properties. For example, the precursors with low melting points behave as liquids in heated canisters, so it may be delivered more consistent vapor pressure, which in turn affects and improves the film properties such as uniformity.

TABLE 2

| Precursor | HfCl₄ | Hf(tBuCp)Cl₃ | Hf(sBuCp)Cl₃ | Hf(sPentylCp)Cl₃ |
|---|---|---|---|---|
| Appearance | White powder | Yellow solid | Yellow solid | Yellow solid |
| Vapor pressure | 1 torr @ 179° C. | 1 torr @ 142° C. | 1 torr @ 144° C. | 1 torr @ 153° C. |
| Melting point | 320 | 59 | 62 | 34 |
| onset (° C.) | | | | |

The disclosed metal chloride precursors may be ZrCpCl₄ Zr(nPrCp)Cl₃, Zr(tBuCp)Cl₃, Zr(sBuCp)Cl₃, Zr(sPentylCp)Cl₃, Hf(tBuCp)Cl₃, Hf(sBuCp)Cl₃, and Hf(sPentylCp)Cl₃.

The disclosed metal chloride precursors may be Hf(sPentylCp)Cl₃.

Using the disclosed metal chloride precursors may obtain unexpected ALD results. When doing the ALD evaluations with ozone, Hf(sBuCp)Cl₃ does not show any ALD behavior, but the ALD windows may be confirmed for Hf(tBuCp)Cl₃ and Hf(sPentylCp)Cl₃. Especially, Hf(sPentylCp)Cl₃ shows unexpected ALD results. It shows ALD window (see FIG. 4) upto 500° C. with excellent step coverage (100%) on a SiO₂ wafer (aspect ratio 25:1) (SEM image (not shown)) for Hf(sPentylCp)Cl₃. For example, However, in the case of Hf(tBuCp)Cl₃, the ALD window is observed upto 450° C.

The disclosed metal chloride precursors may be synthesized from metal cholide, such as HfCl₄ for Hf chloride precursors.

More preferably, the disclosed precursor is Hf(^{s}PentylCp)Cl₃ that may be synthesized by reacting HfCl₄ with ^{s}PentylCpTMS in toluene. It is found that Hf(sPentylCp)Cl₃ has the advantage of not only having a low melting point, 34° C., but also good ALD performance. Hf(^{s}PentylCp)Cl₃ may be one of the greatest alternative precursors for HfCl₄ especially for high temperature ALD process.

The disclosed metal-containing film formed by deposition of the metal-containing film-forming composition containing a metal chloride precursor may be a metal oxide, for example, HfO₂, ZrO₂, HfSiOₓ, HfMOₓ (M is usually a transition metal, e.g., Zr, x is integer), HfN, HfSi or other alloys.

The disclosed metal chloride precursors have the flowing advantages. The disclosed metal chloride precursors may have low melting point, so that they may be liquid with just a little heating. Furthermore not only it has low melting point, but it also has good ALD results such as high ALD window, good film properties such as low impurity level and good crystallinity.

Purity of the disclosed metal-containing film-forming composition including the disclosed metal chloride precursors is greater than 95% w/w (i.e., 95.0% w/w to 100.0% w/w), preferably greater than 98% w/w (i.e., 98.0% w/w to 100.0% w/w), and more preferably greater than 99% w/w (i.e., 99.0% w/w to 100.0% w/w). One of ordinary skill in the art will recognize that the purity may be determined by H NMR and gas liquid chromatography with mass spectrometry. The disclosed metal-containing film-forming composition may contain any of the following impurities: pyrazoles; pyridines; alkylamines; alkylimines; THF; ether; pentane; cyclohexane; heptanes; benzene; toluene; chlorinated metal compounds; lithium, sodium, potassium pyrazolyl. The total quantity of these impurities is preferably below 5% w/w (i.e., 0.0% w/w to 5.0% w/w), preferably below 2% w/w (i.e., 0.0% w/w to 2.0% w/w), and more preferably below 1% w/w (i.e., 0.0% w/w to 1.0% w/w). The composition may be purified by recrystallisation, sublimation, distillation, and/or passing the gas liquid through a suitable adsorbent, such as a 4 Å molecular sieve.

Purification of the disclosed metal-containing film-forming composition may also result in metal impurities at the 0 ppbw to 1 ppmw, preferably 0-500 ppbw (part per billion weight) level. These metal impurities may include, but are not limited to, Aluminum (Al), Arsenic (As), Barium (Ba), Beryllium (Be), Bismuth (Bi), Cadmium (Cd), Calcium (Ca), Chromium (Cr), Cobalt (Co), Copper (Cu), Gallium (Ga), Germanium (Ge), Hafnium (Hf), Zirconium (Zr), Indium (In), Iron (Fe), Lead (Pb), Lithium (Li), Magnesium (Mg), Manganese (Mn), Tungsten (W), Nickel (Ni), Potassium (K), Sodium (Na), Strontium (Sr), Thorium (Th), Tin (Sn), Titanium (Ti), Uranium (U), and Zinc (Zn).

Also disclosed are methods for forming metal-containing layers on a substrate using a vapor deposition process. Applicants believe, and demonstrate in the Deposition Example that follows, that the disclosed metal-containing film-forming compositions are suitable for atomic layer deposition (ALD). More particularly, the disclosed metal-containing film-forming compositions are capable of surface saturation, self-limited growth per cycle, and perfect step coverage on aspect ratios ranging from approximately 2:1 to approximately 200:1, and preferably from approximately 20:1 to approximately 100:1. Additionally, the disclosed metal-containing film-forming compositions have high decomposition temperatures, indicating good thermal stability to enable ALD. The high decomposition temperatures permit ALD at higher temperatures, resulting in films having higher purity.

The disclosed method may be useful in the manufacture of semiconductor, photovoltaic, LCD-TFT, flat panel type devices. The disclosed metal-containing film-forming compositions may be used to deposit metal-containing films using any deposition methods known to those of skill in the art. Examples of suitable deposition methods include chemical vapor deposition (CVD). Exemplary CVD methods include thermal CVD, plasma enhanced CVD (PECVD), pulsed CVD (PCVD), low pressure CVD (LPCVD), sub-atmospheric CVD (SACVD) atmospheric pressure CVD (APCVD), hot-wire CVD (HWCVD, also known as cat-CVD, in which a hot wire serves as an energy source for the deposition process), radicals incorporated CVD, ALD, thermal ALD, plasma enhanced ALD (PEALD), spatial ALD, hot-wire ALD (HWALD), radicals incorporated ALD, and combinations thereof, Super critical fluid deposition may also be used. The deposition method is preferably ALD, PE-ALD, spatial ALD in order to provide suitable step coverage and film thickness control,

The disclosed metal-containing film-forming compositions may be supplied either in neat form in a blend with a suitable solvent, such as ethyl benzene, xylene, mesitylene, decalin, decane, dodecane. The disclosed metal chloride precursors may be present in varying concentrations in the solvent.

The neat or blended disclosed metal-containing film-forming compositions are introduced into a reactor in vapor form by conventional means, such as tubing and/or flow meters. The vapor form may be produced by vaporizing the neat or blended composition through a conventional vaporization step such as direct vaporization, distillation, by bubbling, or by using a sublimator. The neat or blended composition may be fed in liquid state to a vaporizer where it is vaporized before it is introduced into the reactor. Alternatively, the neat or blended composition may be vaporized by passing a carrier gas into a container containing the composition by bubbling the carrier gas into the composition. The carrier gas may include, but is not limited to, Ar, He, N₂, and mixtures thereof. Bubbling with a carrier gas may also remove any dissolved oxygen present in the neat blended composition. The carrier gas and composition are then introduced into the reactor as a vapor,

If necessary, the container containing the disclosed metal-containing film-forming compositions may be heated to a temperature that permits the composition to be in its liquid phase and to have a sufficient vapor pressure. The container may be maintained at temperatures in the range of, for example, approximately 0° C. to approximately 200° C. Those skilled in the art recognize that the temperature of the container may be adjusted in a known manner to control the amount of precursor vaporized.

The reactor may be any enclosure chamber within a device in which deposition methods take place such as without limitation, a parallel-plate type reactor, a cold-wall type reactor, a hot-wall type reactor, a single-wafer reactor, a multi-wafer reactor, a powder ALD reactor, other types of deposition systems under conditions suitable to cause the compounds to react and form the deposition films. One of ordinary skill in the art will recognize that any of these reactors may be used for either ALD or CVD deposition processes.

The reactor contains one more substrates onto which the films will be deposited. A substrate is generally defined as a material on which a process is conducted. The substrates may be any suitable substrate used in semiconductor, photovoltaic, fiat panel, LCD-TFT device manufacturing. Examples of suitable substrates include wafers, such as silicon, silica, glass, GaAs wafers. The wafer may have one more layers of differing materials deposited on it from a previous manufacturing step. For example, the wafers may include a dielectric layer. Furthermore, the wafers may include silicon layers (crystalline, amorphous, porous, etc.), silicon oxide layers, silicon nitride layers, silicon oxy nitride layers, carbon doped silicon oxide (SiCOH) layers, metal, metal oxide, metal nitride layers (Ti, Ru, Ta, etc.) and combinations thereof. Additionally, the wafers may include copper layers noble metal layers (e.g., platinum, palladium, rhodium, and gold). Plastic layers, such as poly(3,4-ethylenedioxythiophene)poly(styrenesulfonate)[PEDOT:PSS] may also be used. The layers may be planar or patterned. The disclosed processes may deposit the metal-containing layer directly on the wafer or directly on one or more layers on top of the wafer (when patterned layers form the substrate). Furthermore, one of ordinary skill in the art will recognize that the terms “film” and “layer” used herein refer to a thickness of some material laid on spread over a surface and that the surface may be a hole, a trench or a line. Throughout the specification and claims, the wafer and any associated layers thereon are referred to as substrates.

The substrate may also be a powder, such as the powder used in rechargeable battery technology. A non-limiting number of powder materials include LNMC (Lithium Nickel Manganese Cobalt Oxide), LCO (Lithium Cobalt Oxide), LFP (Lithium Iron Phosphate), and other battery cathode materials.

The temperature and the pressure within the reactor are held at conditions suitable for ALD. In other words, after introduction of the vaporized disclosed composition into the chamber, conditions within the chamber are such that at least part of the precursor is deposited onto the substrate to form a metal-containing layer. For instance, the pressure in the reactor or the deposition pressure may be held between about 10⁻³ torr and about 100 Torr, more preferably between about 10⁻² and 100 Torr, as required per the deposition parameters. Likewise, the temperature in the reactor or the deposition temperature may be held between about 100° C. and about 600° C., preferably between about 150° C. and about 500° C. One of ordinary skill in the art will recognize that “at least part of the precursor is deposited” means that some all of the precursor reacts with adheres to the substrate.

The temperature of the reactor may be controlled by either controlling the temperature of the substrate holder controlling the temperature of the reactor wall. Devices used to heat the substrate are known in the art. The reactor wall is heated to a sufficient temperature to obtain the desired film at a sufficient growth rate and with desired physical state and composition. A non-limiting exemplary temperature range to which the reactor wall may be heated includes from approximately 50° C. to approximately 600° C. When a plasma deposition process is utilized, the deposition temperature may range from approximately 50° C. to approximately 500° C., preferably, from approximately 100° C. to approximately 500° C., more preferably, from approximately 150° C. to approximately 500° C. Alternatively, when a thermal process is performed, the deposition temperature may range from approximately 100° C. to approximately 600° C.

In addition to the disclosed metal-containing film-forming composition, a co-reactant may be introduced into the reactor. When a target is a conductive film, the co-reactant may be H₂, H₂CO, N₂H₄, NH₃, a primary amine, a secondary amine, a tertiary amine, trisilylamine, a hydrazine N(SiH₃)₃, B₂H₆, Si₂H₆, radicals thereof, and mixtures thereof. Preferably, the co-reactant is H₂ or NH₃. Alternatively, when a target is a dielectric film, the co-reactant may be an oxidizing gas such as one of O₂, O₃, H₂O, H₂O₂, NO, N₂O, NO₂, oxygen containing radicals such as O—OH—, carboxylic acids, formic acid, acetic acid, propionic acid, and mixtures thereof. Preferably, the oxidizing gas is selected from the group consisting of O₃, H₂O₂ and H₂O.

The co-reactant may be treated by a plasma, in order to decompose the reactant into its radical form, N₂ may also be utilized as a nitrogen source gas when treated with plasma. For instance, the plasma may be generated with a power ranging from about 10 W to about 1000 W, preferably from about 50 W to about 500 W. The plasma may be generated present within the reactor itself. Alternatively, the plasma may generally be at a location removed from the reactor, for instance, in a remotely located plasma system. One of skill in the art will recognize methods and apparatus suitable for such plasma treatment.

For example, the co-reactant may be introduced into a direct plasma reactor, which generates plasma in the reaction chamber, to produce the plasma-treated reactant in the reaction chamber. The co-reactant may be introduced and held in the reaction chamber prior to plasma processing. Alternatively, the plasma processing may occur simultaneously with the introduction of the reactant. In-situ plasma is typically a 13.56 MHz RF inductively coupled plasma that is generated between the showerhead and the substrate holder. The substrate and the showerhead may be the powered electrode depending on whether positive ion impact occurs. Typical applied powers in in-situ plasma generators are from approximately 30 W to approximately 1000 W. Preferably, powers from approximately 30 W to approximately 600 W are used in the disclosed methods. More preferably, the powers range from approximately 100 W to approximately 500 W. The disassociation of the co-reactant using in-situ plasma is typically less than achieved using a remote plasma source for the same power input and is therefore not as efficient in reactant dissociation as a remote plasma system, which may be beneficial for the deposition of metal-containing films on substrates easily damaged by plasma.

Alternatively, the plasma-treated co-reactant may be produced outside of the reaction chamber, for example, a remote plasma to treat the co-reactant prior to passage into the reaction chamber.

The ALD conditions within the chamber allow the disclosed metal-containing film-forming composition adsorbed chemisorbed on the substrate surface to react and form a metal-containing film on the substrate. In some embodiments, it is believed that plasma-treating the co-reactant may provide the co-reactant with the energy needed to react with the disclosed metal-containing film-forming composition.

Depending on what type of film is desired to be deposited, an additional precursor compound may be introduced into the reactor. The additional precursor may be used to provide additional elements to the metal-containing film. The additional elements may include Group I elements (lithium, Sodium, potassium), lanthanides (Ytterbium, Erbium, Dysprosium, Gadolinium, Praseodymium, Cerium, Lanthanum, Yttrium), Group IV elements (zirconium, titanium, hafnium), main group elements (germanium, silicon, aluminum), additional different Group V elements, and mixtures thereof. When an additional precursor compound and the metal chloride precursors is utilized, the resultant film deposited on the substrate contains metal-containing compositions in combination with an additional element from the additional precursor. When the additional precursor and the metal chloride precursors are used in more than one ALD super cycle sequences, a nanolaminate film is obtained. For instance, when an additional Li-containing precursor is used, the metal-containing film will contain Li, such as, a lithium hafnium containing LiHfOₓ (x=2-3) film. One of ordinary skilled in the art will recognize the metal-containing films containing Li may be formed by ALD on any types of substrates including a powder.

The disclosed metal-containing film-forming compositions and co-reactants may be introduced into the reactor sequentially (i.e., ALD). The reactor may be purged with an inert gas (e.g., N₂, He, Ar, Kr, or Xe) between the introduction of each of the disclosed metal-containing film-forming compositions, any additional precursors, and the co-reactants. Another example is to introduce the co-reactant continuously and to introduce the metal-containing film-forming composition by pulse, while activating the co-reactant sequentially with a plasma, provided that the metal-containing film-forming composition and the non-activated co-reactant do not substantially react at the chamber temperature and pressure conditions (CW PEALD).

Each pulse of the disclosed metal-containing film-forming compositions may last for a time period ranging from about 0.01 seconds to about 120 seconds, alternatively from about 1 seconds to about 80 seconds, alternatively from about 5 seconds to about 30 seconds. The co-reactant may also be pulsed into the reactor, In such embodiments, the pulse of each may last for a time period ranging from about 0.01 seconds to about 120 seconds, alternatively from about 1 seconds to about 30 seconds, alternatively from about 2 seconds to about 20 seconds. In another alternative, the vaporized disclosed metal-containing film-forming compositions and co-reactants may be simultaneously sprayed from different sectors of a shower head (without mixing of the composition and the reactant) under which a susceptor holding several wafers is spun (spatial ALD).

Depending on particular process parameters, deposition may take place for a varying length of time. Generally, deposition may be allowed to continue as long as desired necessary to produce a film with the necessary properties. Typical film thicknesses may vary from several angstroms to several hundreds of microns, and typically from 2 to 100 nm, depending on the specific deposition process. The deposition process may also be performed as many times as necessary to obtain the desired film.

In one non-limiting exemplary ALD process, the vapor phase of the disclosed metal-containing film-forming compositions is introduced into the reactor, where it is contacted with a suitable substrate. Excess composition may then be removed from the reactor by purging and/or evacuating the reactor. A co-reactant (for example, O₃) is introduced into the reactor where it reacts with the absorbed metal-containing film-forming composition in a self-limiting manner. Any excess co-reactant is removed from the reactor by purging and/or evacuating the reactor. If the desired film is a metal oxide, this two-step process may provide the desired film thickness may be repeated until a film having the necessary thickness has been obtained.

When the co-reactant in this exemplary ALD process is treated with a plasma, the exemplary ALD process becomes an exemplary PEALD process. The co-reactant may be treated with plasma prior subsequent to introduction into the chamber.

Upon obtaining a desired film thickness, the film may be subject to further processing, such as thermal annealing, furnace-annealing, rapid thermal annealing, UV e-beam curing, and microwave annealing and/or plasma gas exposure. Those skilled in the art recognize the systems and methods utilized to perform these additional processing steps. For example, the Nb₂O₅ film may be exposed to a temperature ranging from approximately 200° C. and approximately 1000° C. for a time ranging from approximately 0.1 second to approximately 7200 seconds under an inert atmosphere, an O-containing atmosphere, H-containing atmosphere combinations thereof. Most preferably, the temperature is 400° C. for 3600 seconds under an inert atmosphere or an O-containing atmosphere. The resulting film may contain fewer impurities and therefore may have an improved density resulting in improved leakage current. The annealing step may be performed in the same reaction chamber in which the deposition process is performed. Alternatively, the substrate may be removed from the reaction chamber, with the annealing/flash annealing process being performed in a separate apparatus. Any of the above post-treatment methods, but especially thermal annealing, has been found effective to reduce carbon and nitrogen contamination of HfO₂ film. This in turn tends to improve the resistivity of the film.

After annealing, the metal-containing films deposited by any of the disclosed processes may have a bulk resistivity at room temperature of approximately 50 μohm·cm to approximately 1,000 μohm·cm. Room temperature is approximately 20° C. to approximately 28° C. depending on the season. Bulk resistivity is also known as volume resistivity. One of ordinary skill in the art will recognize that the bulk resistivity is measured at room temperature on the metal-containing films that are typically approximately 50 nm thick. The bulk resistivity typically increases for thinner films due to changes in the electron transport mechanism. The bulk resistivity also increases at higher temperatures.

In another alternative, the disclosed compositions may be used as doping implantation agents. Part of the disclosed metal-containing film-forming composition may be deposited on top of the film to be doped, such as hafnium oxide or zirconium nitride. The metal element, for example Li, then diffuses into the film during an annealing step to form the metal element-doped films, such as LiHfOₓ, LiZrOₓ (x=2-3).

### EXAMPLES

The following non-limiting examples are provided to further illustrate embodiments of the invention. However, the examples are not intended to be all inclusive and are not intended to limit the scope of the inventions described herein.

### Example 1. Synthesis of Hf(^{t}BuCp)Cl₃

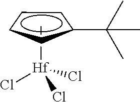

HfCl₄ (114.3 g, 0.36 mol) was dissolved in toluene (800 mL) in a 2 L schlenk flask. After dissolution of ^{t}BuCpTMS (69.4 g, 0.36 mol) in toluene (150 mL), ^{t}BuCpTMS solution was added dropwise to the HfCl₄ solution in a dry ice bath. The mixture was allowed to warm-up to room temperature for overnight with stir to give a dark brown suspension. The organic toluene solvent was removed under vacuum (˜40 mTorr) at 40° C. to give a crude dark brown solid. The dark brown solid was sublimed under vacuum with a cold trap. The product of the dark brown solid was sublimed at ˜100° C. at 30 mTorr resulting in 68.7 g (0.17 mol) of yellow solid with 47% yield.

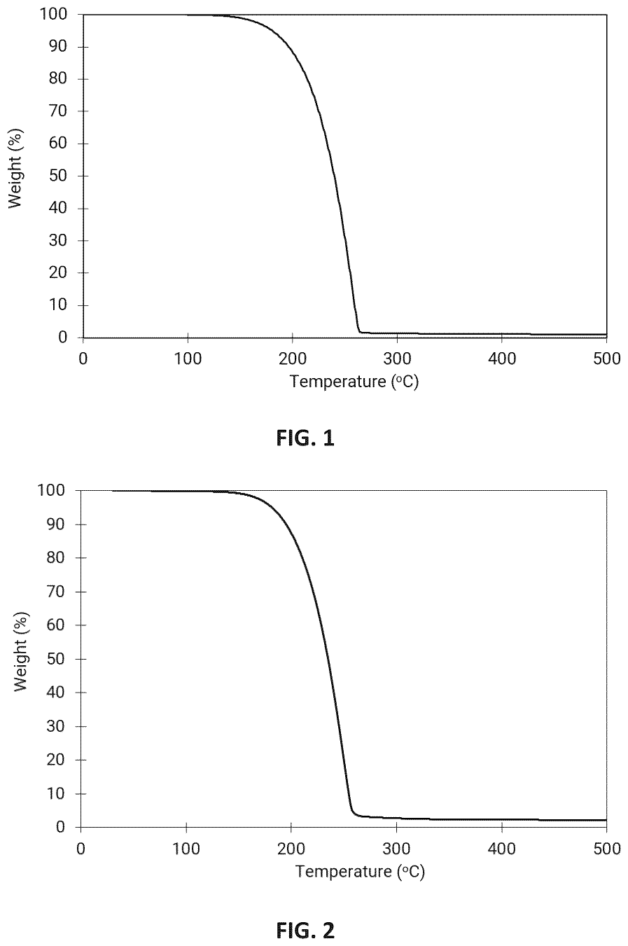

The product was characterized by NMR ¹H (δ, ppm, C₆D₆): 6.60˜5.76 (tt, 4H). 1.05 (s, 9H). FIG. 1 shows A ThermoGravimetric Analysis (TGA) graph demonstrating the percentage of weight with increasing temperature of Hf(^{t}BuCp)Cl₃.

### Example 2. Synthesis of Hf(^{s}PentylCp)Cl₃

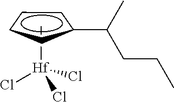

HfCl₄ (81.7 g, 0.26 mol) was dissolved in toluene (600 mL) in a 2 L schlenk flask. After dissolution of ^{s}PentylCpTMS (53.3 g, 0.26 mol) in toluene (120 mL), ^{s}PentylCpTMS solution was added dropwise to the HfCl₄ solution in a dry ice bath. The mixture was allowed to warm-up to room temperature for overnight with stir to give a dark brown suspension. The organic toluene solvent was removed under vacuum (˜40 mTorr) at 40° C. to give a crude dark brown solid. The dark brown solid was sublimed under vacuum with a cold trap. The dark brown solid was sublimed at ˜100° C. at 30 mTorr resulting in a product of 57.5 g (0.14 mol) of yellow solid with 53% yield.

The product was characterized by NMR ¹H (δ, ppm, C₆D₆): 5.92˜5.75 (tt, 4H). 2.75 (m, 2H). 1.24 (m, 2H). 1.09 (m, 2H). 1.00 (d, 3H). 0.74 (t, 3H). FIG. 2 shows a ThermoGravimetric Analysis (TGA) graph demonstrating the percentage of weight with increasing temperature of Hf(^{s}PentylCp)Cl₃.

### Example 3. Synthesis of Zr(^{s}PentylCp)Cl₃

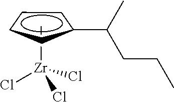

ZrCl₄ (12.5 g, 0.0536 mol) was dissolved 100 mL of toluene and cooled to −65° C. A solution of ^{s}PentylCpTMS (12.3 g, 0.059 mol) dissolved in toluene (20 mL) was added dropwise to the ZrCl₄ solution. The mixture was stirred at room temperature for overnight. After the reaction, solvent was removed under vacuum (˜35 mTorr) at 40° C. to give a crude dark brown solid. The crude was sublimed under vacuum with a cold trap, then the product was sublimed at ˜120° C. at 35 mTorr resulting in a product of 1.17 g of Yellow solid with 6.6% yield.

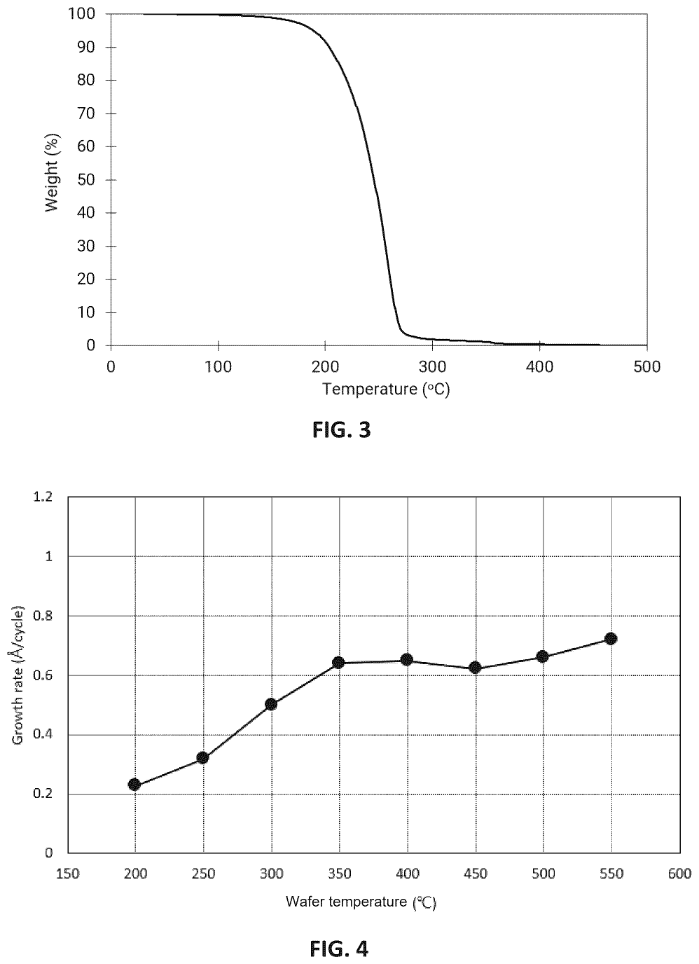

The product was characterized by NMR ¹H (δ, ppm, C₆D₆): 6.23˜6.12 (m, 4H). 3.06 (sext, 1H). 1.14 (m, 2H). 1.18 (m, 2H). 1.12 (d, 3H). 0.80 (t, 3H). FIG. 3 shows a ThermoGravimetric Analysis (TGA) graph demonstrating the percentage of weight with increasing temperature of Zr(^{s}PentylCp)Cl₃.

### Example 4. ALD Using Hf(^{s}PentylCp)Cl₃ with Ozone

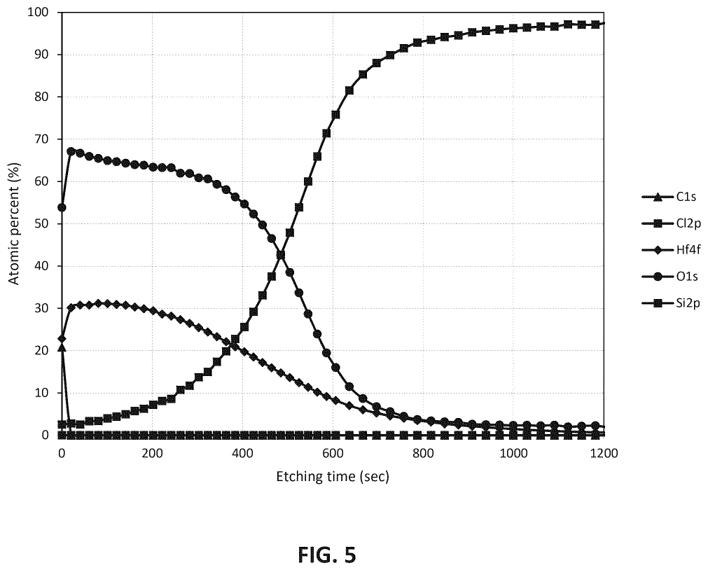

The films were prepared in a shower head type ALD reactor. The precursor vessel was heated at 110° C. Gas delivery lines were heated 20° C. higher than vessel temperature. Carrier gas was supplied to the reactor and precursor line through mass flow controllers. High purity argon was used both as a carrier gas to transfer precursor and as a purge gas to remove byproducts and excess gases from the reactor. Ozone was supplied to the reactor as a co-reactant. Ozone concentration was 300 g/Nm³ and flow rate was 1000 sccm. Typically, the reactor was operated at 0.5-2 torr achieved by argon gas flow with throttle valve. FIG. 4 shows ALD window graph for Hf(^{s}PentylCp)Cl₃ with ozone. SEM image (not shown) showed the step coverage for Hf(^{s}PentylCp)Cl₃ at 500° C./Liner SiO₂ wafer/AR: 25:1. The resulting deposited film was an HfO₂ film. FIG. 5 shows XPS analysis showing film impurities for Hf (^{s}PentylCp)Cl₃ with ozone.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

While embodiments of this invention have been shown and described, modifications thereof may be made by one skilled in the art without departing from the spirit or teaching of this invention. The embodiments described herein are exemplary only and not limiting. Many variations and modifications of the composition and method are possible and within the scope of the invention. Accordingly, the scope of protection is not limited to the embodiments described herein, but is only limited by the claims which follow, the scope of which shall include all equivalents of the subject matter of the claims.

What is claimed is:

1. A method for forming a metal-containing film, the method comprising the steps of:
a) exposing a substrate to a vapor of a metal-containing film-forming composition;
b) exposing the substrate to a co-reactant; and
c) repeating the steps of a) and b) until a desired thickness of the metal-containing film is deposited on the substrate using a vapor deposition process,
wherein the metal-containing film-forming composition comprises a metal chloride precursor having the formula: 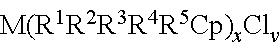
wherein, M is a transition metal, a rare earth element, an alkali metal, or an alkaline earth metal; R¹, R², R³, R⁴ and R⁵ each are independently selected from a hydrogen atom, a C₁ to C₁₀ linear or branched alkyl-group, a C₃ to C₁₀ cyclic alkyl- group, or F, Si, Ge containing C₁ to C₁₀ linear and branched alkyl chain; x and y are integers; provided that x+y equals to the oxidation state of M.

2. The method of claim 1, further comprising the step of
introducing an inert gas purge following the steps a) and b), respectively, to separate each exposure, wherein the inert gas purge uses an inert gas selected from N₂, He, Ar, Kr, or Xe.

3. The method of claim 1, wherein R¹ to R⁵ each is independently selected from H, Me, Et, nPr, iPr, sPr, tBu, sBu, iBu, nBu, tAmyl, sec-pentyl, SiMe₃, SiMe₂H, or SiH₂Me.

4. The method of claim 1, further comprising the step of plasma treating the co-reactant.

5. The method of claim 1, wherein the co-reactant is selected from the group consisting of O₂, O₃, H₂O, H₂O₂, NO, N₂O, NO₂, oxygen containing radicals such as O—OH—, carboxylic acids, formic acid, acetic acid, propionic acid, and mixtures thereof.

6. The method of claim 1, wherein the co-reactant is selected from the group consisting of H₂, H₂CO, N₂H₄, NH₃, a primary amine, a secondary amine, a tertiary amine, trisilylamine, a hydrazine N(SiH₃)₃, B₂H₆, Si₂H₆, radicals thereof, and mixtures thereof.

7. The method of claim 1, wherein the co-reactant is NH₃ or O₃.

8. The method of claim 1, wherein the precursor includes Hf(RCp)Cl₃ and Zr(RCp)Cl₃, wherein R is selected from a hydrogen atom, a C₁ to C₁₀ linear or branched alkyl-group, a C₃-C₁₀ cyclic alkyl- group, or a F, Si, Ge C₁ to C₁₀ containing linear and branched alkyl-group.

9. The method of claim 1, wherein the precursor is Hf(^{t}BuCp)Cl₃.

10. The method of claim 1, wherein the precursor is Hf(^{s}PentylCp)Cl₃.

11. The method of claim 1, wherein the precursor is Zr(^{s}PentylCp)Cl₃.

12. The method of claim 1, wherein the substrate is a powder, wherein the powder comprises one or more of LNMC (Lithium Nickel Manganese Cobalt Oxide), LCO (Lithium Cobalt Oxide), LFP (Lithium Iron Phosphate), and other battery cathode materials.

13. A method of depositing an HfO₂ film or coating the HfO₂ film by an ALD process on a substrate, the method comprising the steps of:
a) exposing the substrate to a vapor of Hf(^{s}PentylCp)Cl₃;
b) exposing the substrate to an oxidizer; and
c) repeating the steps of a) and b) until a desired thickness of the HfO₂ film is formed on the substrate using the ALD process.

14. The method of claim 13, further comprising the step of introducing an inert gas purge following the steps a) and b), respectively, to separate each exposure.

15. The method of claim 13, further comprising the step of plasma treating the oxidizer.

16. The method of claim 13, wherein the oxidizer is ozone.

17. The method of claim 13, wherein the substrate is a powder, wherein the powder comprises one or more of LNMC (Lithium Nickel Manganese Cobalt Oxide), LCO (Lithium Cobalt Oxide), LFP (Lithium Iron Phosphate), and other battery cathode materials.

18. A metal-containing film-forming composition for a vapor deposition process comprising a precursor having the formula: 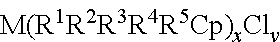
wherein, M is a transition metal, a rare earth element selected from Y or Sc, an alkali metal, or an alkaline earth metal; R¹, R², R³, R⁴ and R⁵ each are independently selected from a hydrogen atom, a C₁ to C₁₀ linear or branched alkyl-group, a C₃ to C₁₀ cyclic alkyl-group, or F, Si, Ge containing C₁ to C₁₀ linear and branched alkyl chain; x and y are integers; provided that x+y equals to the oxidation state of M.

19. The metal-containing film-forming composition of claim 18, wherein R¹ to R⁵ each is independently selected from H, Me, Et, nPr, iPr, sPr, tBu, sBu, iBu, nBu, tAmyl, sec-pentyl, SiMe₃, SiMe₂H, or SiH₂Me.

20. The metal-containing film-forming composition of claim 18, wherein the precursor is selected from the group consisting of Hf(^{t}BuCp)Cl₃, Hf(^{s}PentylCp)Cl₃ and Zr(^{s}PentylCp)Cl₃.
